(19) United States
(12) Patent Application Publication
(10) Pub. No.: US 2018/0090659 A1
(43) Pub. Date: Mar. 29, 2018

(54) Thermoelectric Generator and Method for Producing a Thermoelectric Generator

(71) Applicant: Robert Bosch GmbH, Stuttgart (DE)

(72) Inventors: Tobias Zoller, Nuertingen (DE); Ricardo Ehrenpfordt, Korntal-Muenchingen (DE); Frederik Ante, Stuttgart (DE); Johannes Kenntner, Magstadt (DE)

(21) Appl. No.: 15/566,834

(22) PCT Filed: Mar. 11, 2016
(86) PCT No.: PCT/EP2016/055284

§ 371 Date: Oct. 16, 2017

(30) Foreign Application Priority Data
Apr. 29, 2015 (DE) 10 2015 207 941.4

(51) Int. Cl. H01L 35/34; H01L 35/32

(52) U.S. Cl. CPC H01L 35/34; H01L 35/32

(57) ABSTRACT

A method for producing a thermoelectric generator includes a preparation step, a connection step and an insertion step. In the preparation step, a first substrate, a thermoelectric generator material and a second substrate are prepared. In the connection step, the generator material is connected to the first substrate and the second substrate. In this way, a first side of the generator material is connected to the first substrate in a thermally and electrically conductive manner. A second side of the generator material, opposite the first side, is connected to the second substrate in a thermally and electrically conductive manner. In the insertion step, a support material is inserted between the first substrate and the second substrate, in order to support the first substrate and the second substrate against each other and/or to mechanically connect them together.

### Prior art

The present invention relates to a method for producing a thermoelectric generator, and to a corresponding thermoelectric generator.

The “Internet of Things” (IoT) is identified as one of the most important future developments in information technology. The IoT is understood to mean that, not only people have access to the Internet and are networked via the latter, but that devices are also networked to each other via the Internet. One area of the “Internet of Things” has its base in the area of production automation and home automation. For example, temperature sensors on the heating system, gyroscopes, acceleration sensors, pressure sensors and microphones may be used for this.

The electrical energy required for this can be obtained from the environment by means of so-called “energy harvesters”. The classic harvesters are PV cells for obtaining energy from sunlight, and the thermoelectric generators (TEG), described here, for obtaining energy from a temperature difference, for example on a heating system.

### DISCLOSURE OF THE INVENTION

Against this background, the approach presented here presents a thermoelectric generator (TEG), a method for producing a thermoelectric generator, furthermore a device that uses this method, and finally a corresponding computer program, according to the main claims. Advantageous designs are disclosed by the respective dependent claims and the following description.

A TEG converts a temperature difference on a thermoelectric material into a voltage. The thermoelectric material is usually electrically connected in series and thermally connected in parallel between two substrates. In order to increase the converted voltage to a useful range, a plurality of leads (n-doped and p-doped) on the substrates are electrically connected in series. As a result of the series connection of the many leads, the TEG may lose its functionality completely as a result of one connection being damaged. The maximum stability may be exceeded as a result of thermal and/or mechanical stresses, as a result of which the electrically conductive connection may be impaired and/or broken. In order to increase the load capability of the entire generator, an electrically insulating material may at least partly support the thermal and/or mechanical stresses. As a result, the generator can more easily be machined mechanically and/or integrated into an overall system.

Presented is a thermoelectric generator that has a first substrate, a thermoelectric generator material, electrical connections (track conductors, pads, etc.), and a second substrate, wherein a first side of the generator material is connected in a thermally conductive manner to the first substrate, and a second side of the generator material that is opposite the first side is connected in a thermally conductive manner to the second substrate, wherein there is a support material disposed between the first substrate and the second substrate in order to support the first substrate and the second substrate against each other and/or mechanically connect them to each other.

Additionally presented is a method for producing a thermoelectric generator, wherein the method has the following steps:

providing a first substrate, a thermoelectric generator material and a second substrate;

connecting the generator material to the first substrate and to the second substrate, wherein a first side of the generator material is connected to the first substrate in an electrically and thermally conductive manner, and a second side of the generator material that is opposite the first side is connected to the second substrate in an electrically and thermally conductive manner; and inserting a support material between the first substrate and the second substrate, in order to support the first substrate and the second substrate against each other and/or mechanically connect them to each other.

A substrate may be understood to be a plate-type material. Between the two substrates is the thermoelectric generator material that, in the case of a temperature difference, generates a first voltage, owing to the Seebeck effect. In order to obtain a technically useful voltage, a multiplicity of leads of thermoelectric material may be connected in series. A doping (n- and p-doping) is normally used in the thermoelectric material, in order to adjust the Seebeck coefficient. The support material may be electrically insulating, in order to avoid an electrical short circuit. The support material may be mechanically connected to the first substrate and to the second substrate.

The support material may be inserted between the first substrate and the second substrate, after the first substrate, the generator material and the second substrate have been connected. For example, the support material may be injected between the first substrate and the second substrate.

The support material may be inserted before the second substrate is connected to the generator material. For example, the support material may be applied as a preshaped film to the first substrate. The support material may have recesses for the generator material. The support material may likewise be inserted before the first substrate is connected to the already connected second substrate and generator material.

The support material may be applied to the first substrate. The generator material may be connected to the first substrate in recesses of the support material. As a result of the support material being applied to the first substrate, the support material can be inserted particularly easily. The support material may likewise be applied to the second substrate before the generator material is connected to the second substrate.

The support material may be inserted into an edge region of the first substrate and/or of the second substrate. A lesser material consumption and thermal influencing can be achieved as a result.

The method may have a step of removing the support material. In this case, the support material may be removed, in particular, after the support material has supported shear forces during machining and/or processing of the generator. The removal makes it possible to achieve an increase in the thermal resistance, and consequently an increase in the temperature gradient on the thermoelectric generator material can be achieved.

The method may have a step of coupling the generator. In this case, the first substrate may be thermally coupled to a first carrier substrate, in particular a first printed circuit board. Alternatively or additionally, the second substrate may be thermally coupled to a second carrier substrate, in particular a second printed circuit board. In particular, the first and the second carrier substrate may be at least mechanically connected to each other. Owing to the carrier substrate, or printed circuit board, the generator can be a constituent part of a system and be used for supplying energy to the system. The printed circuit board/the carrier substrate may have heat-conducting elements, in order to couple the temperature difference into and out of the generator.

Additionally advantageous is an embodiment of the approach presented here having a step of coupling the generator, wherein, before the substrates are coupled to the carrier substrates, thermally conductive regions are made in the carrier substrates and are contacted to the substrate in a thermally conductive manner. Such an embodiment of the approach presented here offers the advantage that it is possible to effect electrical rewiring and a possible functional enclosure of the TEG by the carrier substrate, with good thermal coupling and, at the same time, increased mechanical stability. Besides the enclosure, the carrier substrates may also have other electronic components and functionality. The support material may be inserted into a gap between the first substrate and the second substrate. The support material may surround the generator material, in order to support the generator material laterally. The support material may be mechanically connected to the generator material. The generator, with the support material, can thereby withstand even greater loads.

The method may have a step of enclosing the generator in which one of the two substrates is coupled to a carrier substrate, and a housing, in particular a cover, projects over at least a sub-region of the generator. A housing of plastic or metal can protect the generator against environmental influences.

According to a further embodiment of the approach presented here, the method may have a step of enclosing the generator, wherein the enclosure is effected by a plastic, in particular a thermosetting plastic, by injection molding, transfer molding or casting. Such an embodiment of the approach presented here offers the advantage of mechanically stabilizing the TEG and protecting the leads against media such as, for example, moisture. At the same time, the enclosure by means of thermosetting plastic is an established standard process in electronics, and can thus be realized at low cost.

Also favorable is an embodiment of the approach presented here having a step of removing the support material, wherein the support material is removed, in particular, after the step of enclosing has been effected. Such an embodiment of the approach presented here offers the advantage that the support material provides the required additional mechanical stability during enclosure, but at the same time, as the result of being removed after the process, influence caused by the thermal conductivity of the material is no longer relevant.

In addition, according to a further embodiment, the method may have a step of enclosing the generator, wherein, before or in the step of enclosure by a plastic, a tolerance compensating material, in particular a thermally conductive pad, is applied on the surface of the substrate oriented toward the [symbol] enclosure, and is omitted on the side facing away from the substrate. Such an embodiment of the approach presented here offers the advantage that the tolerance compensation can be decomposed together with the support material or, if a thermal pad is used, this can be directly processed concomitantly in the packaging process.

Particularly advantageous is an embodiment of the approach presented here having a step of enclosing the generator wherein, before the step of enclosure by a plastic, a damming material, in particular a plastic, is applied at least to a sub-region of the vertical faces of the generator, such that it leaves the region between the substrates free of the plastic of the enclosure. Such an embodiment of the approach presented here offers the advantage that, owing to the damming material, it is possible to prevent the region between the substrates from being filled in an undefined manner by the thermosetting housing material. In addition, the material may be realized such that it can be removed again after the packaging process.

The approach presented here additionally creates an apparatus that is designed to perform, control or implement the steps of a variant of a method presented here, in corresponding items of equipment. This embodiment variant of the invention, in the form of a control device, also enables the object on which the invention is based to be achieved in a rapid and efficient manner.

An apparatus in this case may be understood to mean an electrical device that processes sensor signals and that, in dependence thereon, outputs control signals and/or data signals. The apparatus may have an interface, which may be realized as hardware and/or software. If realized as hardware, the interfaces may be, for example, part of a so-called system ASIC, which includes a great variety of functions of the apparatus. It is also possible, however, for the interfaces to be separate integrated circuits or to be composed, at least partly, of discrete components. If realized as software, the interfaces may be software modules that, for example, are present on a microcontroller in addition to other software modules.

Also advantageous is a computer program product or computer program, having program code, which can be stored on a machine-readable carrier or storage medium such as a semiconductor memory, a hard disk memory or an optical memory, and which is used to perform, implement and/or control the steps of the method according to one of the embodiments described above, in particular when the program product or program is executed on a computer or an apparatus.

The approach presented here is explained exemplarily in greater detail in the following on the basis of the appended drawings. There are shown:

FIG. 1 a block diagram of a thermoelectric generator according to an exemplary embodiment of the present invention;

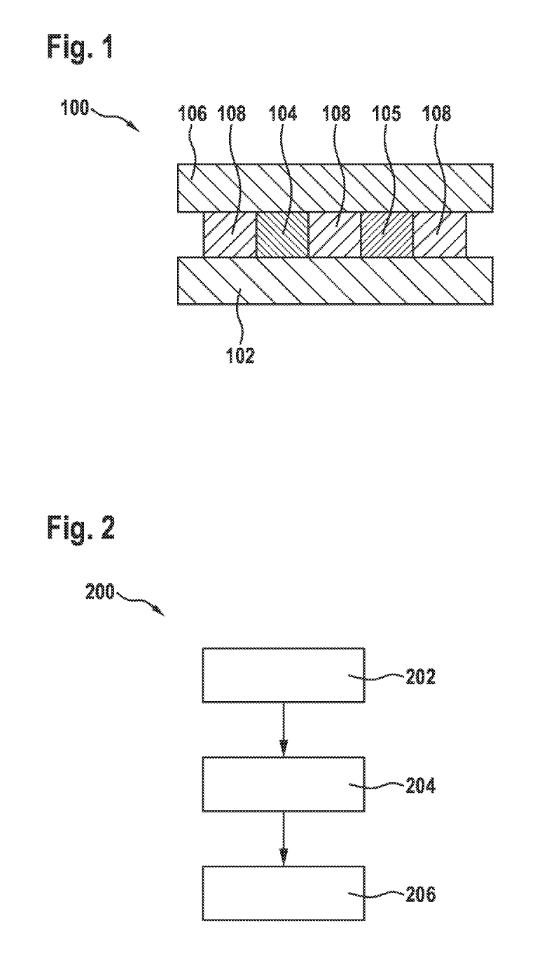

FIG. 2 a flow diagram of a method for producing a thermoelectric generator according to an exemplary embodiment of the present invention; and

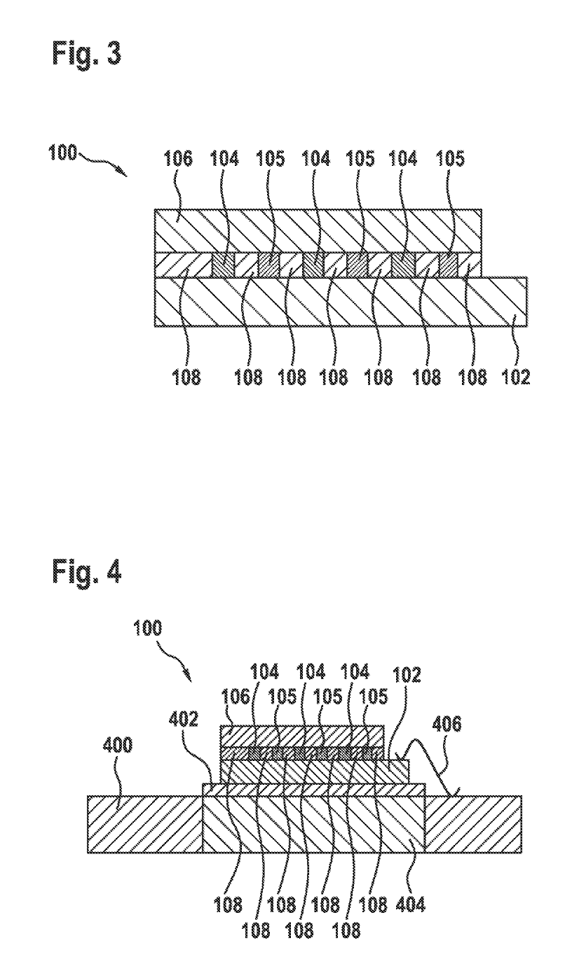

FIGS. 3 to 13 representations of thermoelectric generators according to various exemplary embodiments of the present invention.

In the following description of favorable exemplary embodiments of the present invention, elements, represented in the various figures, that are similar in their effect are denoted by the same or similar references, and description of these elements is not repeated.

FIG. 1 shows a block diagram of a thermoelectric generator 100 according to an exemplary embodiment of the present invention. The thermoelectric generator 100 has a first substrate 102, a thermoelectric generator material 104 and 105 (n-doped and p-doped) and a second substrate 106. A first side of the generator materials 104 and 105 is connected in a thermally conductive manner to the first substrate 102. A second side of the generator materials 104 and 105 that is opposite the first side is connected in a thermally conductive manner to the second substrate 106. There is a support material 108 disposed between the first substrate 102 and the second substrate 106. The support material 108 mechanically connects the first substrate 102 to the second substrate 106, and supports the substrates 102, 106 against each other.

It is also conceivable for the generator material 104 to be on the one substrate, and the generator material 105 to be on the second substrate, and these then to be thus joined together.

FIG. 2 shows a flow diagram of a method 200 for producing a thermoelectric generator according to an exemplary embodiment of the present invention. A thermoelectric generator such as that represented in FIG. 1, for example, can be produced by use of the method 200 described here. The method 200 has a step 202 of providing, a step 204 of connecting, and a step 206 of inserting. In the step 202 of providing, a first substrate of the thermoelectric generator, a thermoelectric generator material and a second substrate of the thermoelectric generator are provided. In the step 204 of connecting, the generator is connected to the first substrate and the second substrate. In this case, the first side of the generator material is connected in a thermally conductive manner to the first substrate. A second side of the generator material that is opposite the first side is connected in a thermally conductive manner to the second substrate. In the step 206 of inserting, a support material is inserted between the first substrate and the second substrate, in order to mechanically connect the first substrate and the second substrate to each other and support them against each other.

FIG. 3 shows a representation of a thermoelectric generator 100 according to an exemplary embodiment of the present invention. The generator 100 corresponds substantially to the generator in FIG. 1. In addition to this, the generator material 104 and 105 is realized in the form of a multiplicity of thermoelectric leads 104 and 105 between the first substrate 102 and the second substrate 106. The support material 108 is disposed in the spaces between the leads 104, 105, and fills a gap between the first substrate 102 and the second substrate 106.

A thermoelectric generator (TEG) 100 normally consists of an upper substrate 106 and a lower substrate 102 that are connected to each other via leads 104 and 105 of thermoelectric material 104, 105. The leads 104 and 105 are connected thermally in parallel and electrically in series. Within the TEG 100, in the presence of a temperature gradient, a voltage is generated as a result of the Seebeck effect.

In the case of current assembly concepts for “packaging” TEGs 100 in electronic housings, the TEG 100 is rigidly connected, on the upper side 106 and lower side 102, to the cold side and hot side of the housing by means of thermally conductive materials. Thermomechanical strains are thereby transferred directly to the leads 104 and 105 of the TEG 100. These strains can result in damage to the leads 104, 105, and consequently to the entire module 100. Already in the assembly process, the TEG 100 is subjected to high thermomechanical and mechanical loads.

In the case of the approach presented here, an assembly material 108 is used to protect a thermoelectric generator 100 in a mechanically robust manner against influences in the process chain and in production.

In order to impart robustness to the thermoelectric generator 100, a filler material 108 is inserted into the clearances or spaces of a thermoelectric generator 100. The clearances or spaces extend laterally between the thermoelectrically active leads 104 and vertically between the at least two substrates 102, 106 of the thermoelectric generator 100.

The filler material 108 in this case may be inserted temporarily, and removed after the assembly process chain, or may remain permanently in the TEG 100.

The thermal conductivity of the permanent filler material 108 in this case is in the range of ≦1.5 W/mK, in particular in the range of ≦0.5 W/mK, in particular in the range of ≦0.3 W/mK.

In general, the permanent or temporary filler material 108 may be, in particular, materials from the group of polymers, which are inserted by dispensing, jetting, injection molding, diffusing, transfer molding at wafer level or chip level, or by deposition in the TEG production process. The temporary material 108 may be removed by chemical, wet-chemical or dry-chemical means, in particular thermally, at a temperature of ≦500° C., in particular ≦280° C., in particular ≦200° C.

The approach presented here makes it possible to achieve a reduction in the mechanical loading caused, inter alia, by thermomechanical stress, on the thermoelectric leads 104, 105 of the TEG 100 during the packaging and production process.

Furthermore, it is possible to achieve a reduction in the mechanical influences on the TEG 100 that are caused by stresses during production. For example, these loads occur when the sensor modules, fitted with the TEG 100, are being singled out of a larger panel by sawing. Mechanical loads such as impacts, free fall or moisture during transport, during storage or handling by the end user may also occur.

The use of a temporary material 108, for example a thermally decomposable polymer 108 or a water-soluble adhesive 108, enables the region between the leads 104 and 105 of the TEG 100 to be freed of the material 108 again after loading, in order to ensure the original thermal performance.

The temporary material 108 additionally offers protection against moisture in differing process steps.

The structure presented here includes at least one thermoelectric generator 100, which is composed of two substrates 102, 106. These substrates 102, 106 are connected to each other by thermoelectric material 104, 105 in the form of “leads”.

A thermoelectric generator 100 having a filler material 108, for example underfill, is represented in FIG. 3. The thermal conductivity of the filler material 108 in this case is in the range of ≦1.5 W/mK, in particular in the range of ≦0.5 W/mK, in particular in the range of ≦0.3 W/mK. The filler material 108 is, in particular, a material from the group of polymers, that is inserted by dispensing, jetting, injection molding, diffusing, transfer molding at wafer level or chip level, or by deposition in the TEG production process. The filler material 108 is used to increase the robustness of the TEG 100 against mechanical loads. The underfill 108 of filler material in this case is disposed between a TEG lower side 102 and a TEG upper side 106.

In an exemplary embodiment, the thermoelectric generator 100 is represented with a temporary stabilization 108. The two substrates 102, 106 may be referred to as TEG upper side 106 and TEG lower side 102. In addition to the substrates 102, 106, the thermoelectric leads 104, 105 and the temporary stabilization 108 are represented. During operation, the temperature T1 is present on the upper side 106, and the temperature T2 is present on the lower side. The difference of these two temperatures is approximately the usable temperature gradient.

FIG. 4 shows a representation of a thermoelectric generator 100, according to an exemplary embodiment of the present invention, which is attached in a thermally conductive manner on a printed circuit board 400. The generator 100 corresponds substantially to the generator in FIG. 3. In addition, the first substrate 102 is connected to a heat-conducting region 404 of the printed circuit board 400 by use of an adhesive layer 402. The generator is electrically connected, via wires 406, to printed conductors in and/or on the printed circuit board 400.

In FIG. 4, a thermoelectric generator 100, as described in FIG. 3, is adhesive-bonded to a substrate 400 or to a printed circuit board 400. Alternatively, the generator may be attached by soldering. A region 404 of good thermal conductivity is realized beneath the TEG 100, in order to effect good conduction of the temperature to the TEG 100.

In other words, in FIG. 4 a thermoelectric generator 100 having temporary stabilization 108 is adhesive-bonded by means of adhesive 402 to a substrate 400, or to a printed circuit board 400 by means of a thermal connection 404, for example of copper.

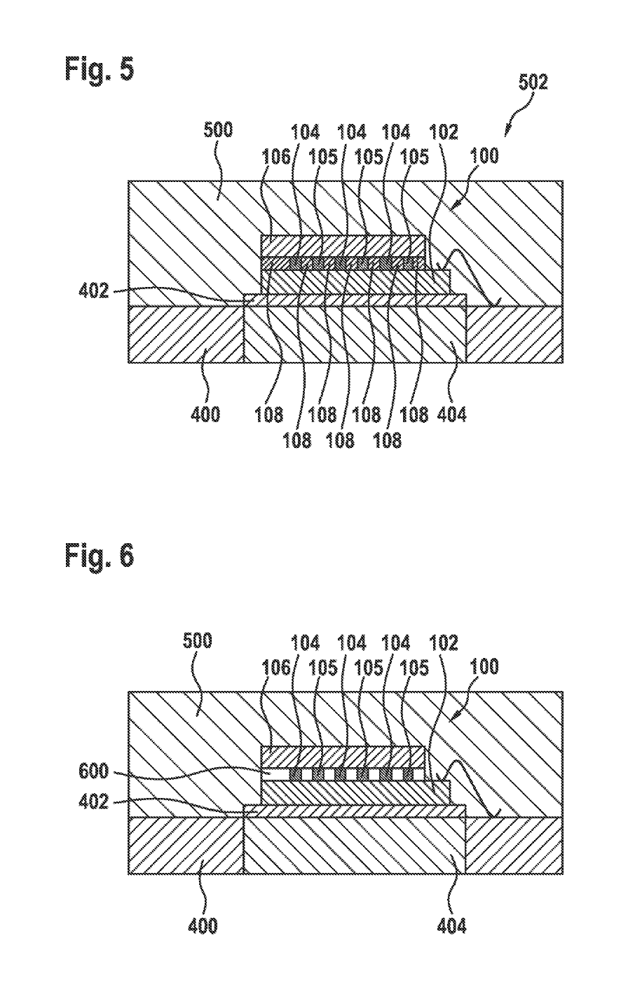

FIG. 5 shows a representation of a thermoelectric generator 100, according to an exemplary embodiment of the present invention, which is enclosed by a housing 500. The generator 100 corresponds substantially to the generator in FIGS. 3 to 4. In addition, the generator 100 and the surface of the printed circuit board 400 are covered by potting compound 500. The generator 100 is thereby protected against environmental influences.

In other words, FIG. 5 shows a sensor module 502 having temporary or permanent stabilization 108 for a thermoelectric generator 100.

In FIG. 5, the structure described above is also additionally enclosed. This enclosure 500 is represented by a mold compound 500. By means of the temporary stabilization 108, the mold compound 500 can be prevented from entering the region between the leads 104, 105. Following the actual molding process, the temporary stabilization 108 can be removed. As an alternative to the mold compound 500, a metal cover, for example, may be used.

In other words, the thermoelectric generator 100, having the temporary stabilization 108, is adhesive-bonded to a substrate 400 or to a printed circuit board 400, and coated with mold compound 500.

FIG. 6 shows a representation of a thermoelectric generator 100 according to an exemplary embodiment of the present invention. The generator 100 corresponds substantially to the generator in FIG. 5. Unlike the latter, in this case the support material has been removed following enclosure with the potting compound 500, such that an air gap 600 has been produced in the gap between the first substrate 102 and the second substrate 106. The air gap 600 is bridged by the thermoelectric generator material 104, 105.

In an exemplary embodiment, the support material has been removed by thermal decomposition. In other words, the support material is vaporized.

FIG. 6 shows the embodiment example from FIG. 5 with temporary material already having been decomposed. In this case, the decomposition is effected through the mold compound 500. In other words, FIG. 6 shows a thermoelectric generator 100, with decomposed temporary stabilization, which is adhesive-bonded onto a substrate (printed circuit board), and coated with mold compound 500.

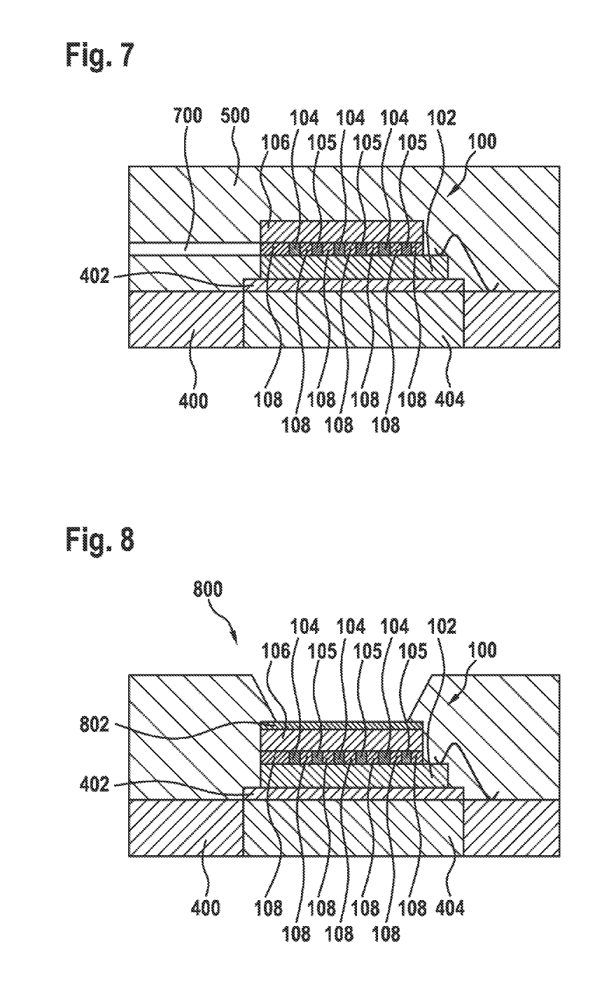

FIG. 7 shows a representation of a thermoelectric generator 100 according to an exemplary embodiment of the present invention. The generator 100 corresponds substantially to the generator in FIG. 5. In addition, the housing 500 has a channel 700, through which the off-gas, which can be produced during the decomposition of the support material 108, can escape. In this case, the channel 700 is substantially parallel to the printed circuit board 400, within the potting compound 500. The channel 700 runs from the gap between the substrates to a surface of the housing 500.

In FIG. 7 is an exemplary embodiment having an additional decomposition channel 700, for removing the temporary stabilization 108 by a suitable subsequent step. The channel 700 may be realized horizontally, as represented, or alternatively may also be realized vertically. For example, the channel 700 may be realized as a laser opening from below and/or from above.

FIG. 8 shows a representation of a thermoelectric generator 100 according to an exemplary embodiment of the present invention. The generator 100 corresponds substantially to the generator in FIG. 5. In addition, the housing 500 has an opening 800 in the region of the generator 100. In the opening 800, the second substrate 106 is exposed. In order to avoid mechanical and thermomechanical stresses in the production processes or during use, there is a tolerance compensating layer or a thermal pad 802 disposed on the second substrate 106. The tolerance compensating layer may be decomposed when the support material 108 is decomposed.

In FIG. 8, the mold compound 500 on the upper side has been removed by a suitable tool. In addition, a temporary tolerance compensating layer or a thermal pad 802 may be realized on the upper side of the TEG 100. Likewise, as a possible variation, a metal cover may be used, which, being of a suitable shape, functions as a heat sink for the TEG 100. In this case, an additional temporary tolerance compensation or thermal pad 802 and a mold compound opening 800 have been added to the previous exemplary embodiments.

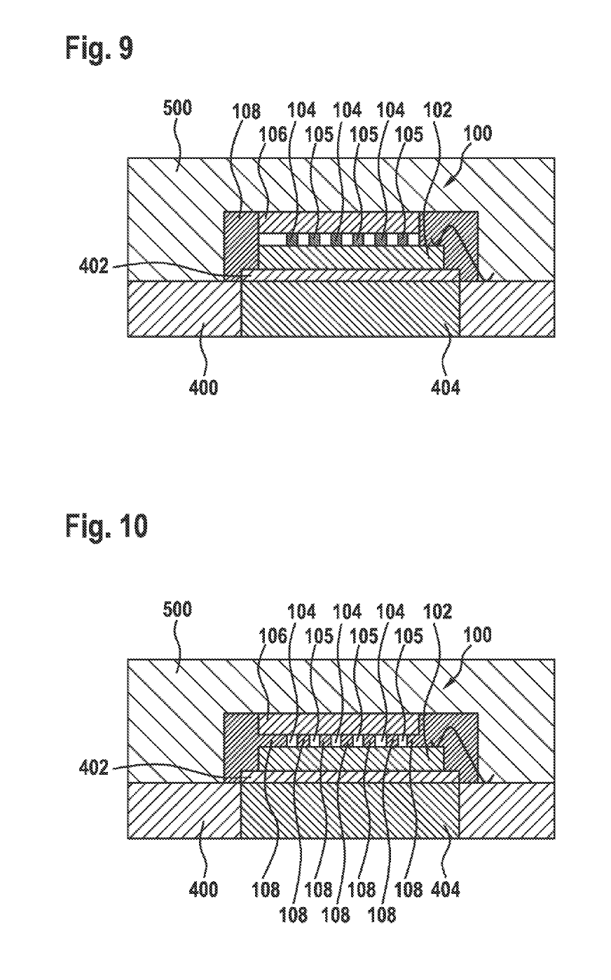

FIG. 9 shows a representation of a thermoelectric generator 100 according to an exemplary embodiment of the present invention. The generator 100 corresponds substantially to the generator in FIG. 5. Unlike the latter, in this case the support material 108 is disposed substantially on lateral faces of the substrates 102, 106. There is no support material disposed in the gap between the substrates 102, 106. The support material 108 is removed after the housing 500 is disposed over the generator 100.

In FIG. 9, the temporary stabilization 108 is realized as a sheath, or wraparound dam. In an exemplary embodiment, the sensor likewise has a decomposition channel.

FIG. 10 shows a representation of a thermoelectric generator 100 according to an exemplary embodiment of the invention. The generator 100 corresponds substantially to the generator in FIG. 5. In addition to the support material 108 in the gap, there is a further support material 108, as in FIG. 9, disposed on the lateral faces of the substrates 102, 106.

In FIG. 10, the temporary stabilization 108 is additionally realized around the thermoelectric generator 100. In other words, the structure presented here is represented with an extended temporary stabilization 108 on the sides of the thermoelectric generator 100.

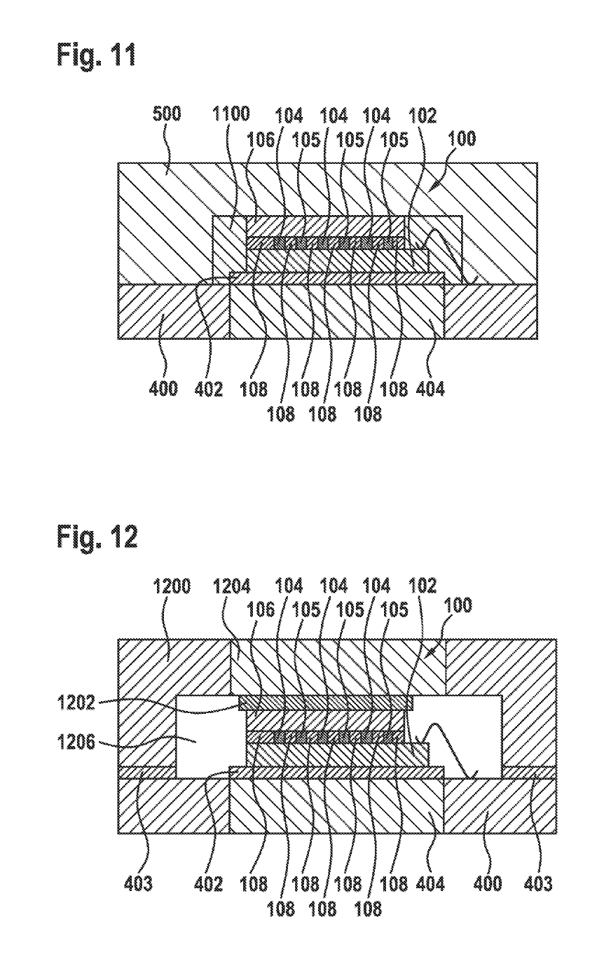

FIG. 11 shows a representation of a thermoelectric generator 100 according to an exemplary embodiment of the present invention. The generator 100 corresponds substantially to the generator in FIG. 5. In addition, there is a damming material 1100 disposed on lateral faces of the substrates 102, 106. The damming material 1100 is permanent and, unlike the support material 108, is not removed after the housing 500 has been formed.

Shown in FIG. 11 is an exemplary embodiment in which the temporary stabilization 108 is used together with a damming material 1100 of poor thermal conductivity. The decomposition of the temporary stabilization 108 is effected either through the dam 1100 or likewise requires a decomposition channel, not represented. In other words, FIG. 11 shows a structure having temporary stabilization 108 and damming material 1100 of poor thermal conductivity extending around the TEG 100.

FIG. 12 shows a representation of a thermoelectric generator 100 according to an exemplary embodiment of the present invention. The generator 100 corresponds substantially to the generator in FIG. 4. In addition to this, a second printed circuit board 1200 is connected to the second substrate 106. The second substrate 106 is connected to a second heat-conducting region 1204 of the second printed circuit board 1200 by use of a further adhesive layer 1202. The second printed circuit board 1200 has a recess 1206, in which the generator 100 is disposed. The printed circuit boards 400, 1200 are mechanically connected to each other in an edge region, and thus form a kind of housing.

In an exemplary embodiment, the generator 100 is disposed in the recess 1206, and is connected to the second printed circuit board 1200 before the second printed circuit board 1200 and the generator 100 are connected to the first printed circuit board 400. The two printed circuit boards 1200 and 400 are connected to each other via a contact material 403. This contact material may be an adhesive, a soldered connection or a bonded connection. In an ideal case, this material is of poor thermal conductivity, in order to avoid a thermal short circuit between the two printed circuit boards, past the TEG.

FIG. 12 shows an exemplary embodiment having a plurality of printed circuit boards 400, 1200. The printed circuit boards 400, 1200 form a cavity 1206, in which a sensor system and the TEG 100 can be disposed. The connection of the two printed circuit boards 400, 1200 may be effected by a third printed circuit board (not represented), more precisely a printed circuit board ring, such that the upper 1200 and lower 400 printed circuit board can be realized without large topography. In this case, the thermal connection 1204 within the printed circuit board 1200 is realized by a copper insert 1204 or thermal vias 1204 in the printed circuit board 1200. In other words, FIG. 12 shows an exemplary embodiment in which two printed circuit boards 400, 1200 are connected to each other, and a cavity 1206 is formed in the middle. The printed circuit boards 400, 1200 may be connected by adhesive, solder and/or a thermal pad.

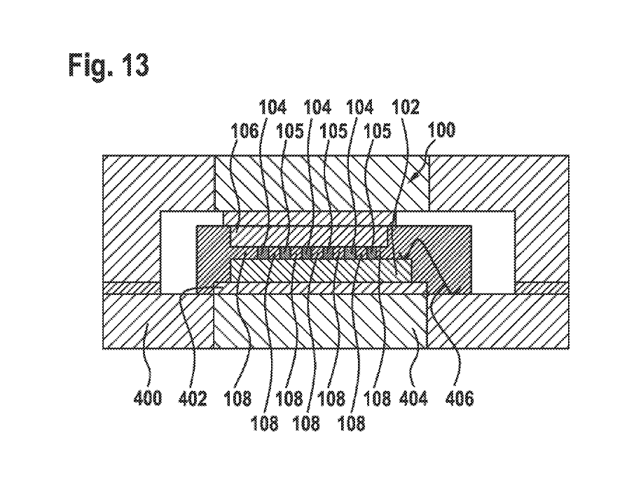

FIG. 13 shows a representation of a thermoelectric generator 100 according to an exemplary embodiment of the present invention. The generator 100 corresponds substantially to the generator in FIG. 12. In addition to this, the support material 108, as in FIG. 10, is disposed laterally around the generator 100. Unlike the latter, the wires 406 in this case are fully embedded in the support material. The wires 406 are thereby protected against mechanical loads during production of the generator 100.

Represented in FIG. 13 is a further variant in which the temporary stabilization 108 goes beyond the sides of the TEG 100 and additionally protects the wire bond 406 against mechanical stress in the process.

The exemplary embodiments described and shown in the figures have been selected merely as examples. Differing exemplary embodiments may be combined with each other in their entirety or in respect of individual features. Also, one exemplary embodiment may be complemented by features of another exemplary embodiment.

Further, the method steps presented here may be repeated, and executed in a sequence other than that described.

If an exemplary embodiment includes an “and/or” link between a first feature and a second feature, this is to be construed such that the exemplary embodiment according to one embodiment has both the first feature and the second feature, and according to a further embodiment has either only the first feature or only the second feature.

1. A method for producing a thermoelectric generator comprising:
providing a first substrate, a thermoelectric generator material and a second substrate;
connecting the generator material to the first substrate and to the second substrate, wherein a first side of the generator material is connected to the first substrate in a thermally and electrically conductive manner, and a second side of the generator material that is opposite the first side is connected to the second substrate in a thermally and electrically conductive manner; and
inserting a support material between the first substrate and the second substrate to support the first substrate and the second substrate against each other and/or mechanically connect them to each other.

2. The method as claimed in claim 1, wherein:
inserting the support material includes inserting the support material between the first substrate and the second substrate, after the first substrate, the generator material, and the second substrate have been connected.

3. The method as claimed in claim 1, wherein:
inserting the support material includes inserting the support material before the second substrate is connected to the generator material.

4. The method as claimed in claim 1, wherein:
inserting the support material includes applying the support material to the first substrate; and
the generator material is connected to the first substrate in recesses of the support material.

5. The method as claimed in claim 1, wherein:
inserting the support material includes inserting the support material into an edge region of at least one of the first substrate and the second substrate.

6. The method as claimed in claim 1, further comprising:
removing the support material, wherein:
the support material is removed after the support material has supported shear forces during at least one of machining and processing of the generator.

7. The method as claimed in claim 1, further comprising:
coupling the generator, wherein:
the first substrate is thermally coupled to a first carrier substrate and/or the second substrate is thermally coupled to a second carrier substrate.

8. The method as claimed in claim 1, further comprising:
enclosing the generator, wherein:
one of the two substrates is coupled to a carrier substrate, and
a housing projects over at least a sub-region of the generator.

9. The method as claimed in claim 8, further comprising:
removing the support material, wherein:
the support material is removed after the generator has been enclosed.

10. The method as claimed in claim 1, further comprising:
enclosing the generator, wherein; before or during enclosure of the generator by a plastic, a tolerance compensating material is applied on a surface of the substrate oriented toward the enclosure and is omitted on a side facing away from the substrate.

11. The method as claimed in claim 1, further comprising:
enclosing the generator, wherein:
before of enclosure of the generator by a plastic, a damming material is applied at least to a sub-region of vertical faces of the generator such that the damming material leaves a region between the substrates free of the plastic of the enclosure.

12. An apparatus configured to perform, implement and/or control a method as claimed in claim 1.

13. A thermoelectric generator, having comprising:
a first substrate;
a thermoelectric generator material; and
a second substrate, wherein:
a first side of the generator material is connected in a thermally conductive manner to the first substrate;
a second side of the generator material that is opposite the first side is connected in a thermally conductive manner to the second substrate; and
a support material disposed between the first substrate and the second substrate is configured to support the first substrate and the second substrate against each other and/or mechanically connect them to each other.

14. The method as claimed in claim 7, wherein:
the first carrier substrate is a printed circuit board; and
the second carrier substrate is a printed circuit board.

15. The method as claimed in claim 7, wherein:
the first carrier substrate and the second carrier substrate are at least mechanically connected to each other.

16. The method as claimed in claim 8, wherein the housing is a cover.

17. The method as claimed in claim 10, wherein the tolerance compensating material is a thermally conductive pad.

18. The method as claimed in claim 11, wherein the damming material is a plastic.
